(19) United States
(12) Patent Application Publication
(10) Pub. No.: US 2008/0116938 A1
(43) Pub. Date: May 22, 2008

(54) Hybrid Keeper Circuit for Dynamic Logic

(76) Inventors: Hung C. Ngo, Austin, TX (US); Peter Juergen Klim, Austin, TX (US); Jente B. Kuang, Austin, TX (US); Jethro C. Law, Austin, TX (US); Trong V. Luong, Austin, TX (US); Abraham Mathews, Austin, TX (US)

Correspondence Address: IBM CORP (WSM);C/O WINSTEAD SECHREST & MINICK P.C., PO BOX 50784, DALLAS, TX, 75201, US

(21) Appl. No.: 11/560,440

(22) Filed: Nov. 16, 2006

(51) Int. Cl. H03K 19/096

(52) U.S. Cl. 326/95

(57) ABSTRACT

A dynamic logic gate has a dynamic node pre-charged in response to a pre-charge phase of a clock signal and a logic tree with a plurality of logic inputs for evaluating the dynamic node during an evaluate phase of the clock signal in response to a Boolean combination of the logic inputs. The dynamic node is coupled to an output with an inverting logic circuit. A hybrid keeper circuit, coupled to the dynamic node, uses a parallel NFET and a first PFET to produce the same current as a larger PFET when operated with a high voltage power supply. The common node of the combination is coupled to the dynamic node by second PFET larger than the first PFET in one embodiment. At high voltage, the hybrid keeper provides a strong keeper current when potential noise is highest. The hybrid keeper current is automatically reduced at low voltage allowing performance to be maintained while keeping the effective noise immunity of the high voltage operation.

### TECHNICAL FIELD

The present invention relates in general to metal oxide silicon (MOS) dynamic logic circuits and in particular to dynamic logic circuits using keeper circuitry to improve noise tolerance.

### BACKGROUND INFORMATION

Modern data processing systems may perform Boolean operations on a set of signals using dynamic logic circuits. Dynamic logic circuits are clocked. During the precharge phase of the clock, the circuit is preconditioned, typically by precharging an internal node (dynamic node) of the circuit by coupling to a power supply rail. During an evaluate phase of the clock, the Boolean function being implemented by the logic circuit is evaluated in response to the set of input signal values appearing on the inputs during the evaluate phase. (For the purposes herein, it suffices to assume that the input signals have settled to their “steady-state” values for the current clock cycle, recognizing that the input value may change from clock cycle to clock cycle.) Such dynamic logic may have advantages in both speed and the area consumed on the chip over static logic. However, the switching of the output node with the toggling of the phase of the clock, each cycle may consume power even when the logical value of the input is otherwise unchanged.

This may be appreciated by referring to FIG. 1 illustrating an exemplary two-input NAND dynamic logic gate. The dynamic logic gate includes inputs 109 coupled to the gates of N channel field effect transistors (NFETs) 101-102. During an evaluate phase (logic one) of Clk 104, NFET 106 is turned ON, and if all inputs 109 are a logic one, dynamic node 108 is pulled low (logic zero), and Out 107 transitions to a logic one via inverter 110. During the precharge phase (logic zero) of Clk 104, dynamic node 108 is precharged to a logic one via P channel field effect transistor (PFET) 112. A keeper 100 employs PFET 114 to maintain the charge on dynamic node 108 if it evaluates to a logic one.

Dynamic logic may use a footer device (e.g., NFET 106) or not. In the case the footer NFET 106 is not used, the inputs 109 must be timed to be valid during the evaluate phase of Clk 104. Regardless, dynamic circuits rely on the ability to pre-charge the dynamic node to a logic one state in advance of having valid logic inputs valid. In logic circuitry with a wide input fan-in, there are many parallel paths that may be coupled to the dynamic node by one or more select devices, leakage current may make it difficult to hold the logic state on the dynamic node until the start of the next evaluation cycle. This is especially true as device size decreases.

The sharp increase of leakage currents in scaled technologies severely limits the robustness of dynamic circuits, especially for high fan-in wide dynamic gates, commonly employed in the performance critical units of high-performance microprocessors. A strong keeper 100 (PFET 114 and inverter 110) is necessary in the pre-charged state or after the completion of evaluation to compensate for the larger leakage current and to hold the right state at the dynamic node. Charge sharing is another major concern in dynamic circuits, which causes voltage drooped on the dynamic node, thus degrading the noise margins.

A large number of design techniques have been developed in an effort to improve dynamic circuits. Feedback keepers have been used to prevent floating nodes, internal nodes have been pre-charged to eliminate charge sharing, and weak complementary pull-up networks have been used to improve noise tolerance. However, these remedial techniques improve dynamic circuit noise tolerance at the expense of circuit are, speed, and/or power consumption. The amount of overhead increases dramatically when the noise tolerance requirement is increased along with the continuous down-scaling of process technology.

The simple feedback keeper 100 is effective and easy to design. However, choosing the right size for the keeper is a dilemma. On one hand, a strong keeper with a large keeper PFET 114 is required to achieve high gate noise tolerance. On the other hand, a large keeper PFET 114 leads to significant contention during normal gate switching which will degrade performance. A conditional keeper circuit may be designed wherein the keeper is degated during the evaluation phase, however this is not effective against gate noise because the gate is not adequately protected during the switching time window. Noise immunity is very difficult to improve without significantly affecting circuit performance because the gate should not switch before it “determines” whether the input is noise or a real logic signal.

When the dynamic node 108 is a logic one, the voltage across the keeper PFET 114 is a minimum and it only supplies the leakage current that acts to discharge dynamic node 108. If the dynamic node 108 evaluates to a logic zero, the logic tree 103 must discharge the dynamic node 108. As the voltage drops during discharge, keeper PFET 114 comes out of saturation and the supplied current starts increasing. The logic tree 103 must sink this additional current to continue discharging dynamic node 108 towards the logic zero evaluation level. The maximum average current that the keeper 114 can supply determines its strength relative to the speed at which the dynamic node 108 can be evaluated and thus determines the delay through to Out 107. Once the threshold of inverter 110 is reached, the voltage drive (gate-to-source voltage) of keeper PFET 114 decreases and the current supplied by PFET 114 starts to decrease and the logic tree 103 no longer has to sink as much current. This combination exhibits a negative resistance characteristic; the voltage across PFET 114 is increasing and its supplied current decreases. Therefore, the strength of keeper PFET 114 relative to the speed or delay is determined by the maximum average current keeper PFET 114 can supply during the time the dynamic node voltage is decreasing towards a logic zero. To cause a true logic zero evaluation of the dynamic node 108, the logic tree 103 must sink the maximum current from keeper PFET 114 until the feedback via inverter 110 starts reducing the maximum current. The evaluation logic states remain active for the entire evaluation time. On the one hand, it would be desirable to require as much of the evaluation time as possible for the logic tree to pull the dynamic node 108 to the threshold voltage of inverter 110, however, this would assure the greatest circuit delay.

Noise causes a transient condition at the dynamic node. During pre-charge, PFET 112 supplies current to the dynamic node 108 and has the entire pre-charge time to charge the dynamic node. Noise is only a factor if it causes the dynamic node 108 to discharge to a logic zero level when the logic inputs are set to evaluate dynamic node 108 to a logic one. Keeper PFET 114 is saturated at this time and its ability to supply increasing current when the dynamic node is being discharged by a noise signal determines the noise immunity. If a noise pulse can discharge the dynamic node to a point where the feedback via inverter 110 starts to decrease drive, then the noise immunity is compromised. Noise immunity, therefore, is determined by the maximum small signal current that can be supplied over the allowed voltage variation of the dynamic node 108.

One of the primary noise components is noise that is capacitively coupled to one input from an adjacent input. This type of noise increases as the power supply voltage increases and decreases as the power supply voltage decreases. Therefore to have high noise immunity for the high noise case, it is desirable to make keeper PFET 114 large.

To minimize delay, it is necessary to discharge the dynamic node 108 quickly when the logic tree 103 evaluates the dynamic node 108 to a logic zero. If logic tree 103 has several stacked NFETs then the required logic one voltage necessary to turn ON all the NFETs is increased. This condition is more easily met when the power supply voltage is high, therefore, a strong keeper PFET 114 will provide both good noise immunity and gate delay when the power supply voltage is high. However, when the power supply voltage is low, the logic one voltage is may not be adequate to quickly turn ON the stacked NFETs in the logic tree 103 to a low impedance and therefore circuit delay suffers. This has led to complex keeper designs for scalable logic circuits that provide different strength keeper devices gated by the power supply voltage level. However, this increases the area and required control signals for each dynamic circuit.

There is, therefore, a need for a dynamic logic circuit design with keeper circuitry that has high noise immunity at high voltage and reduced strength at low voltage without any required control signals.

### SUMMARY OF THE INVENTION

A hybrid keeper circuit employs a parallel combination of a second PFET and an NFET in addition to the inverter and the first PFET used in conventional keeper circuits. The second PFET is in cascode with the first PFET and is has its gate coupled to the ground or logic zero potential. The source of the second PFET is coupled to the positive or logic one voltage potential. The NFET is coupled in parallel with the second PFET with both its gate and drain coupled to the positive voltage potential and its source coupled to the drain of the first PFET forming a common node. When the power supply (PS) voltage is high, there is enough voltage compliance such that the common node will generate sufficient forward bias on the NFET so that it supplies additional keeper current to the dynamic node making the keeper circuitry strong. At a low PS voltage, the affect of the NFET is mitigated causing the keeper circuit to weaken thus maintaining the lower voltage performance.

The foregoing has outlined rather broadly the features and technical advantages of the present invention in order that the detailed description of the invention that follows may be better understood. Additional features and advantages of the invention will be described hereinafter which form the subject of the claims of the invention.

### BRIEF DESCRIPTION OF THE DRAWINGS

For a more complete understanding of the present invention, and the advantages thereof, reference is now made to the following descriptions taken in conjunction with the accompanying drawings, in which:

FIG. 1 illustrates, in schematic form, a prior art dynamic logic gate with a standard keeper circuit;

FIG. 2 is a circuit schematic of a dynamic logic gate with a hybrid keeper circuit according to an embodiment of the present invention;

FIG. 3 is a circuit schematic of a dynamic logic gate with a hybrid keeper circuit according to another embodiments of the present invention;

FIG. 4 is a circuit schematic of a dynamic logic gate with a hybrid keeper circuit according an embodiment of the present invention and a standard keeper circuit used in a complex logic circuit;

FIG. 5 is a circuit schematic of a dynamic logic gate with a hybrid keeper circuit according to an embodiment of the present invention with a static latch; and

FIG. 6 is a high level functional block diagram of a processing unit suitable for practicing inventive principles of the present invention.

### DETAILED DESCRIPTION

In the following description, numerous specific details are set forth to provide a thorough understanding of the present invention. However, it will be obvious to those skilled in the art that the present invention may be practiced without such specific details. In other instances, well-known circuits may be shown in block diagram form in order not to obscure the present invention in unnecessary detail. For the most part, details concerning timing, data formats within communication protocols, and the like have been omitted inasmuch as such details are not necessary to obtain a complete understanding of the present invention and are within the skills of persons of ordinary skill in the relevant art.

In the following, the term “strong” keeper or device is used to designate a device that is able to supply a high relative current. A keeper or keeper circuit is one that is used to hold the state of a node that would normally be floating at a preset level.

Refer now to the drawings wherein depicted elements are not necessarily shown to scale and wherein like or similar elements are designated by the same reference numeral through the several views.

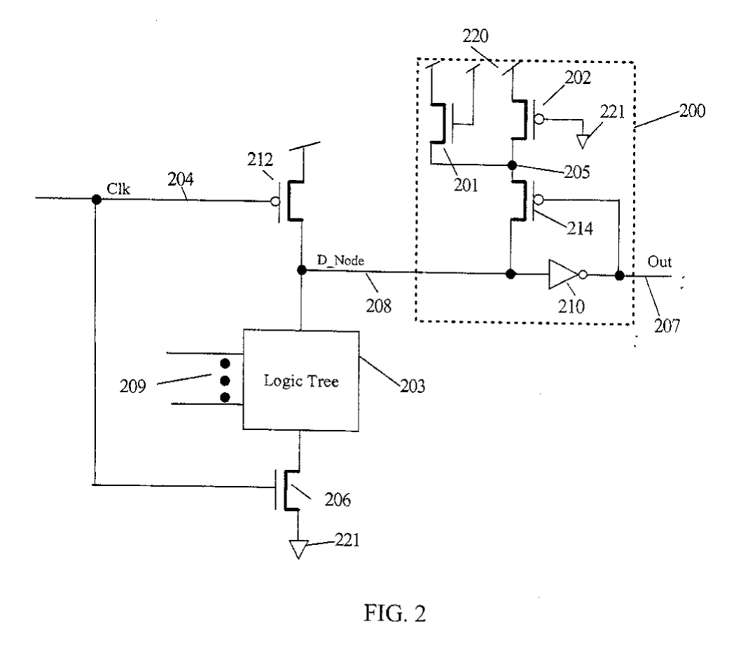

FIG. 2 is a circuit diagram of a dynamic logic circuit powered by a power supply with voltage potentials 220 and 221 and having a keeper circuit configured according to an embodiment of the present invention. To interface to down stream circuitry, inverter 210 would normally be used to isolate the dynamic node. In the following FIGS., this inverter may be considered as part of the keeper circuitry to simplify the explanation.

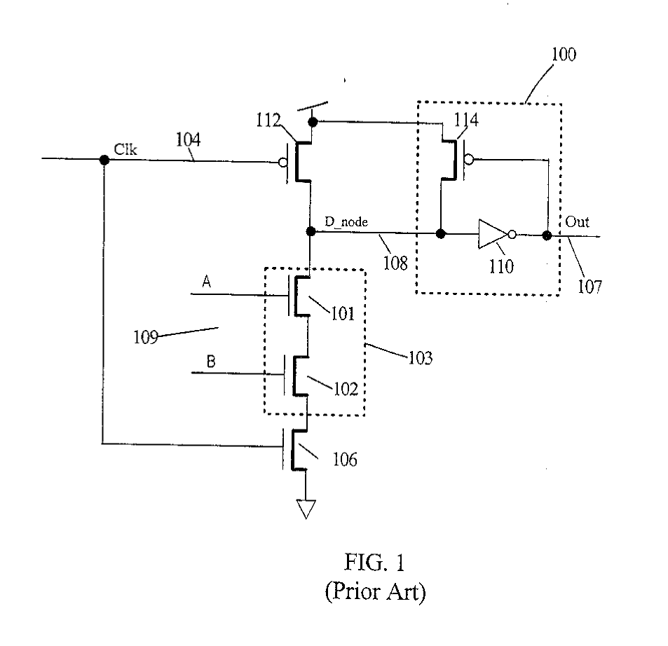

Logic tree 203 has logic inputs 209 and is coupled to precharge PFET 212 and footer NFET 206. The dynamic node (D_node) 208 is pre-charged by PFET 212 when Clk 204 is a logic zero and evaluated to the Boolean combination of logic inputs 209 when Clk 204 is a logic one. The keeper circuit 200, according to an embodiment of the present invention, comprises NFET 201, PFET 202, PFET 214 and inverter 210. NFET 201 and PFET 202 are coupled in parallel. If D_node 208 evaluates to a logic one, then the charge on D D_node 208 has to be maintained during the evaluation time when Clk 204 is a logic one. Even though the net effect of the logic states of logic inputs 209 maintains the logic one at D_node 208, various devices in logic tree 203 may switch ON (e.g., because of noise) causing capacitance change at D D_node 208 which in turn affects the logic one level of D_node 208. The role of a keeper circuit 200 (e.g., as described in FIG. 1) is to provide current to maintain the charge on D_node 208 when it evaluates to a logic one and to release this current when D_node 208 evaluates to a logic zero.

It is desirable to make PFET 214 a strong device so that the noise immunity is high when the circuit is operated at a high power supply (PS) voltage 220. In the present invention, PFET 214 is sized as a strong device and the parallel connection of NFET 201 and PFET 202 combine to provide the current for PFET 214. NFET 210 has its drain and gate coupled to PS 220 and its source coupled to common node 205. PFET 202 has its source coupled to PS 220 and its gate coupled to ground or the logic zero potential and is operated as a “current source” which supplies a fixed current at a particular gate-to-source voltage. Since NFET 201 and PFET 202 combine to supply the current for PFET 214, PFET 202 may be a device smaller than PFET 214.

When PS voltage 220 is high, assume D_node 208 is a logic zero and Out 207 is a logic one thereby turning PFET 214 OFF. PFET 202 is always biased ON and its current drives node 205 towards PS voltage 220 until PFET 202 is saturated. Since node 205 is near PS voltage 220, the gate-to-source voltage of NFET 201 is near zero thereby gating NFET 201 to the OFF state.

When D_node 208 transitions to a logic one during pre-charge, Out 207 will transition toward a logic zero thereby turning PFET 214 ON. Since PFET 214 is a large device, it is configured to conduct more current than PFET 202 at a same gate-to-source voltage. Node 205 is near PS voltage 220 and thus PFET 214 turns ON to a low impedance state and can sink more current than PFET 202 can supply alone. Thus, when PFET 214 turns ON it will cause the voltage on node 205 to start to decrease. However, when the voltage on node 205 decreases the gate-to-source voltage of NFET 201 increases turning it ON thus supplying current to PFET 214. The extra current of NFET 201 will cause node 205 to settle at a voltage level where the combined current supplied by PFET 202 and NFET 201 equals the current that PFET 214 sinks. PS voltage 220 is required to be of a high enough level such that node 205 can drop to a voltage potential that provides enough gate-to-source voltage drive for both NFET 201 and PFET 214 when D_node 208 is receiving current.

When D_node 208 transitions toward a logic zero during evaluation, Out 207 will start a transition towards a logic one when the threshold of inverter 210 is reached. As soon as Out 207 starts increasing, the gate-to-source voltage of PFET 214 starts to decrease thereby decreasing its current. Since the dynamic source impedance of node 205 is high, a small change in the current through PFET 214 will cause the voltage of node 205 to increase thereby decreasing the gate-to-source voltage of NFET 201 reducing its supplied current. Likewise, PFET 202 will be driven into towards saturation as the voltage on node 205 increases thereby decreasing the current from PFET 202. Therefore, as PFET 214 turns OFF, NFET 201 turns OFF and PFET 202 saturates allowing D_node 208 to be evaluated to a logic zero.

When PS voltage 220 has a low value, the logic one level necessary to gate stacked NFETs in logic tree 203 to an ON state is not high enough to quickly discharge D_node 208 if a standard keeper circuit (e.g., keeper 100) is used. However, the present invention solves this problem. A low PS voltage 220 reduces the voltage compliance available to turn PFET 214 ON thus reducing the amount of current it can sink. At the same time, a low PS voltage 220 reduces the voltage compliance available to turn both NFET 201 and PFET 202 thus reducing the amount of current they can source in combination.

Again, when D_node 208 transitions to a logic one during pre-charge, Out 207 will transition to a logic zero turning ON PFET 214. Since PFET 214 is a large device, it is configured to conduct more current than PFET 202 at a same gate-to-source voltage. Node 205 is near PS voltage 220 and thus PFET 214 turns ON to a high current. When the current PFET 214 can sink exceeds the source current of PFET 202, the voltage on node 205 starts to decrease. However, when the voltage on node 205 decreases, the gate-to-source voltage of NFET 201 increases thereby turning it ON, thus supplying additional current to PFET 214. The extra current of NFET 201 will cause node 205 to settle at a voltage level where the combined current of PFET 202 and NFET 201 equals the current in PFET 214. In this case, PS voltage 220 is low and node 205 cannot drop to the voltage potential that provided the same current as when PS voltage 220 was high. The low value of PS voltage 220 reduces the gate-to-source voltage of all the devices. The lower gate-to-source voltages causes hybrid keeper 200 to operate at a lower current and allows improved low voltage performance. Since the noise generation due to capacitive coupling is lower at a low value of PS voltage 220, hybrid keeper 200 maintains an effective noise immunity comparable to when PS voltage 220 is high.

The hybrid keeper circuit 200 provides a strong keeper with high current when PS 220 is high and potential noise generation is high thus ensuring an acceptable noise immunity. Likewise, since the logic one level is high, there is sufficient drive for the logic tree 203 to turn ON stacked NFETS to an adequate level to sink the high keeper current during a logic zero evaluation of D_node 208. When operated at a low value for PS voltage 220, the voltage compliance is not adequate to turn ON both NFET 201 and PFET 214 to the same current as in the high voltage case. Since the keeper current is reduced during a low value for PS voltage 220, the logic one level is adequate to normalize the circuit delay during low voltage operation. Lower noise generation during low voltage operation insures that the hybrid keeper 200 provides the same “effective” noise immunity as in the high voltage operation.

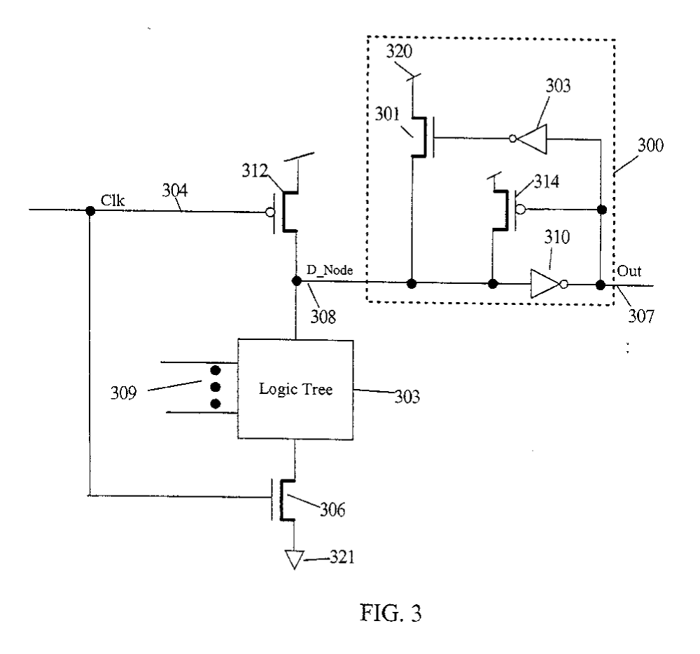

FIG. 3 is schematic of a dynamic logic circuit powered by a power supply with voltage potentials 320 and 321 and having a hybrid keeper 300 according another embodiment of the present invention using parallel devices. In this embodiment, PFET 314 and NFET 301 are sized to operate as one large PFET at a high PS voltage 220. D_node 308 is charged by PFET 312 when Clk 304 is a logic zero and the logic states of logic inputs 309 are evaluated by logic tree 303 when Clk 304 is a logic one.

When PS voltage 320 is a high level, assume D_node 308 is a logic zero and Out 307 is a logic one turning PFET 314 OFF to a high impedance state via inverter 310. Likewise, inverter 303 turns NFET 301 OFF. When D_node 308 transitions toward a logic one during pre-charge, Out 307 will transition to a logic zero turning PFET 314 and NFET 301 both ON and the combination of their currents will aid in pre-charging D-node 308. Once charged, D_node 308 will sufficiently saturate PFET 314 and NFET 301 so that their combined current will provide only leakage current.

If D_node 308 evaluates to a logic one, then any negative transition of D_node 308 due to noise will pull both PFET 314 and NFET 301 out of saturation supplying additional current to maintain the logic one state of D_node 308. At a high operating voltage, the logic one states are adequate to turn ON the NFETs in logic tree 303 sufficiently to sink the combined current of NFET 210 and PFET 314 with minimal delay. During low voltage operation, the gate-to-source voltages available to drive both NFET 301 and PFET 314 are reduced thereby reducing the maximum keeper current available.

The hybrid keeper 300 provides a strong keeper with high current when PS 320 is high and potential noise generation is high thus ensuring an acceptable noise immunity. Likewise, since the logic one levels are high, there is sufficient drive for the logic tree 303 to turn ON stacked NFETS to an adequate level to sink the high keeper current during a logic zero evaluation of D_node 308. When operated at a low value of PS voltage 320, the gate-to-source voltages are not adequate to turn ON both NFET 301 and PFET 314 to the same current as in the high voltage case. However, since the keeper current is reduced during a low value for PS voltage 320, the logic one level is adequate to normalize the circuit delay during low voltage operation. Lower noise generation during low voltage operation insures that the keeper circuit 300 provides the same “effective” noise immunity as in the high voltage operation.

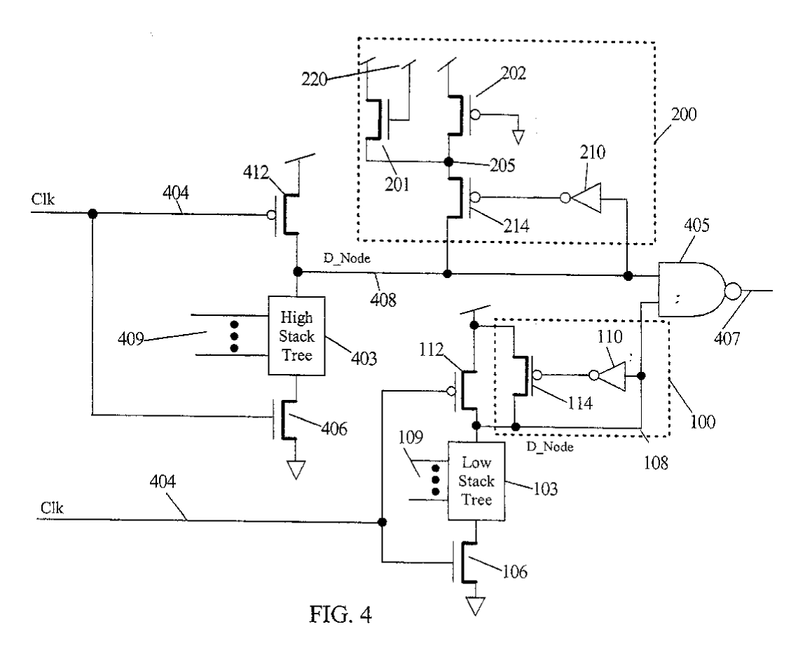

FIG. 4 is a circuit diagram of a complex gate 400 where a first dynamic circuit uses standard keeper 100 and a second dynamic circuit uses a hybrid keeper 200 according to embodiments of the present invention. The first dynamic circuit comprises a pre-charge PFET 412 coupled to Clk 404 for charging D_node 408. Logic tree 403 comprises a high stack of NFET devices receiving logic inputs 409 and thus may suffer from degraded low voltage operation with a strong keeper, thus the hybrid keeper 200 is used. Hybrid keeper 200 comprises inverter 210, PFETs 202 and 214, and NFET 201 and its operation was explained in detail relative to FIG. 2. The second dynamic circuit comprises a pre-charge PFET 112 coupled to Clk 404 for charging D_node 108. Logic tree 103 comprises a low stack of NFET devices and thus may perform adequately in low voltage operation if a strong keeper was used. The standard keeper 100 is used with the low stack logic tree 103. Standard keeper 100 comprises inverter 110 and PFET 114 and its operation was explained in detail relative to FIG. 1. The logic states of D_node 408 and D_node 108 are combined in a NAND gate 405 to produce an output 407.

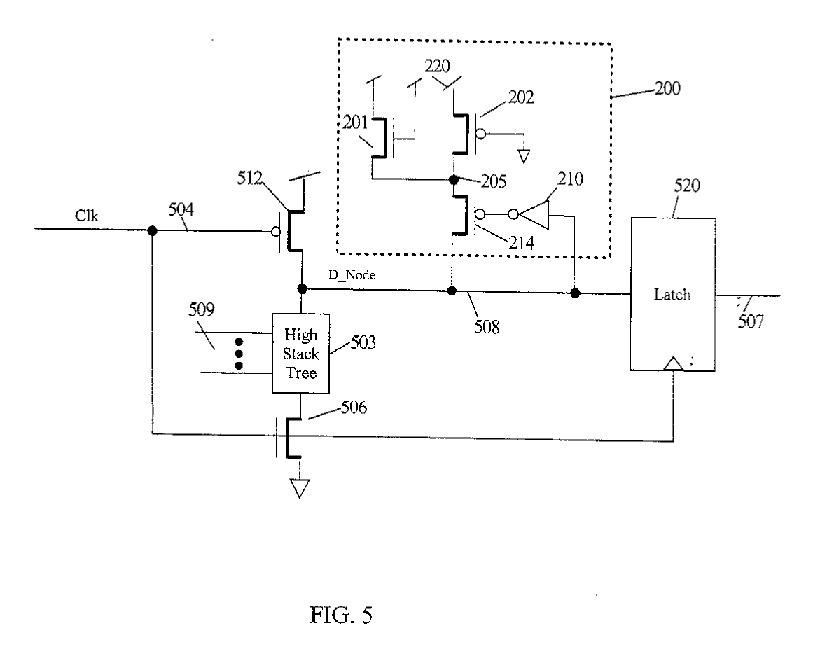

FIG. 5 is a circuit diagram of a static latch 520 used with a hybrid keeper 200 configured according to one embodiment of the present invention. Hybrid keeper 200 comprises inverter 210, PFETs 202 and 214, and NFET 201 and its operation was explained in detail relative to FIG. 2. The dynamic circuit comprises a pre-charge PFET 512 coupled to Clk 504 for charging D D_node 508. Logic tree 503 comprises a high stack of NFET devices receiving logic inputs 509 and may suffer from degraded low voltage operation with a strong keeper, thus it is used the hybrid keeper 200. Latch 520 latches states of D_node 508 when Clk 504 transitions to a logic zero.

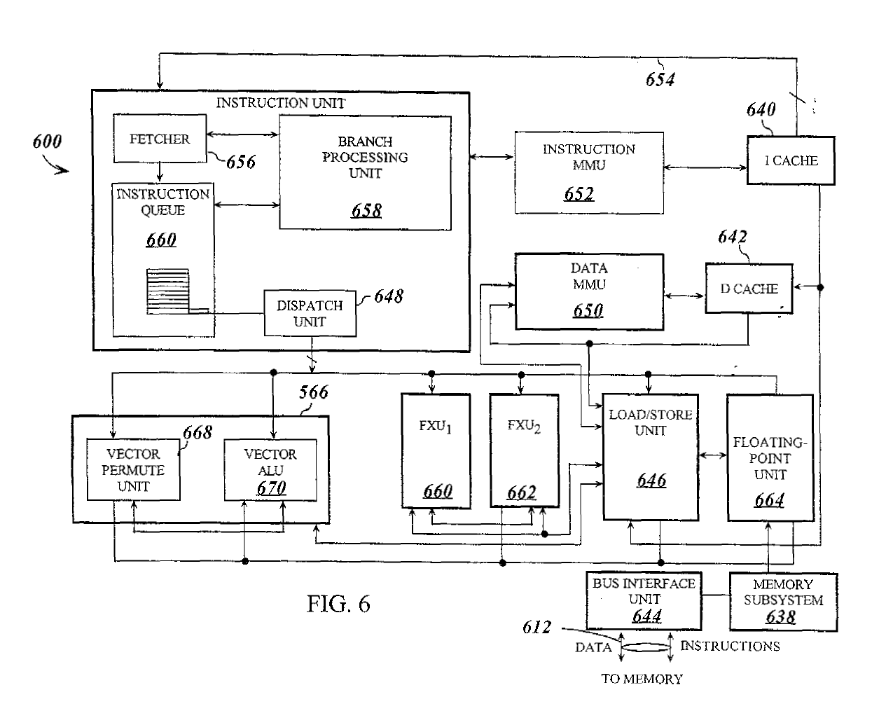

FIG. 6 is a high level functional block diagram of selected operational blocks that may be included in a central processing unit (CPU) 600 suitable for practicing inventive principles of the present invention. In the illustrated embodiment, CPU 600 includes internal instruction cache (I-cache) 640 and data cache (D-cache) 642 which are accessible to memory (not shown in FIG. 4) through bus 612, bus interface unit 644, memory subsystem 638, load/store unit 646 and corresponding memory management units: data MMU 650 and instruction MMU 652. In the depicted architecture, CPU 600 operates on data in response to instructions retrieved from I-cache 640 through instruction dispatch unit 648. Dispatch unit 648 may be included in instruction unit 654 which may also incorporate fetch unit 656 and branch processing unit 658 which controls instruction branching. An instruction queue 660 may interface fetch unit 656 and dispatch unit 648. In response to dispatched instructions, data retrieved from D-cache 642 by load/store unit 646 can be operated upon by one of fixed point unit (FXU) 630, FXU 662 or floating point execution unit (FPU) 664. Additionally, CPU 600 provides for parallel processing of multiple data items via vector execution unit (VXU) 666. VXU 666 includes vector permute unit 668 which performs permutation operations on vector operands, and vector arithmetic logic unit (VALU) 670 which performs vector arithmetic operations, which may include both fixed-point and floating-point operations on vector operands. VALU 670 may be implemented using hybrid keepers 200-300 in combination with dynamic circuits as shown in FIGS. 2-5 and in accordance with the present inventive principles. Other units may also employ dynamic logic gates with hybrid keepers 200-300 according to embodiments of the present invention.

Although the present invention and its advantages have been described in detail, it should be understood that various changes, substitutions and alterations can be made herein without departing from the spirit and scope of the invention as defined by the appended claims.

What is claimed is:

1. A hybrid keeper circuit for a dynamic logic circuit powered with a power supply and having a dynamic node coupled to a logic output with a first inverting logic gate, the dynamic node pre-charged in response to a pre-charge phase of a clock signal and evaluated in response to a Boolean combination of a plurality of logic inputs and an evaluate phase of the clock signal, the hybrid keeper circuit comprising:
an NFET having a drain terminal coupled to a first voltage potential of the power supply, a gate terminal coupled to a first gate signal, and a source terminal; and
a first PFET having a gate terminal coupled to a second gate signal, a source terminal coupled to the first voltage potential, and a drain terminal coupled to the source terminal of the NFET thereby forming a common node coupled to the dynamic node,
wherein a level of a current coupled from the commode node to the dynamic node corresponds to a combination of a source current of the NFET and a drain current of the first PFET and is determined in response to a level of the first gate signal, a level of the second gate signal, and a voltage level of the common node.

2. The hybrid keeper circuit of claim 1, wherein the gate terminal of the first PFET is coupled to a second voltage potential of the power supply as the first gate signal.

3. The hybrid keeper circuit of claim 2, wherein the gate terminal of the NFET is coupled to the first voltage potential as the second gate signal.

4. The hybrid keeper circuit of claim 3, wherein the current from the common node is coupled to the dynamic node by a second PFET having a source terminal coupled to the common node, a drain terminal coupled to the dynamic node and a gate terminal coupled to the output of the first inverting logic gate.

5. The hybrid keeper circuit of claim 4, wherein the gate-to-source voltage of the NFET and the level of the common node determine the source current of the NFET.

6. The hybrid keeper circuit of claim 5, wherein the gate-to-source voltage of the first PFET and the level of the common node determine the drain current of the first PFET.

7. The hybrid keeper circuit of claim 6, wherein the output of the first inverting circuit is latched to an output in response to the clock signal.

8. The hybrid keeper circuit of claim 1, further comprising a second inverting logic circuit having an output coupled to the gate of the NFET and an input coupled to the output of the first inverting circuit and the gate-to source voltage of the NFET is the difference between the output level of the second inverting circuit and a voltage level of the dynamic node.

9. The hybrid keeper circuit of claim 8, wherein the gate of the first PFET is coupled to the output of the first inverting logic circuit and the gate to source voltage of the first PFET is the difference between the first voltage potential and a voltage of the output of the first inverting logic gate.

10. The hybrid keeper circuit of claim 9, wherein the common node is coupled directly to the dynamic node.

11. A processor comprising:
a central processing unit (CPU);
a memory coupled to the CPU for storing instructions and data, the
CPU having one or more dynamic logic gates powered by a power supply and each having a dynamic node pre-charged in response to a pre-charge phase of the clock signal, a logic tree for evaluating the dynamic node in response to a Boolean combination of the plurality of logic inputs and an evaluate phase of the clock signal, an inverting logic gate coupling the dynamic node to a logic output of the dynamic logic gate, and a hybrid keeper circuit coupled to a dynamic node of the one or more dynamic logic gates, the hybrid keeper circuit having a first inverting logic gate with an input coupled to the dynamic node and an output, an NFET having a drain terminal coupled to a first voltage potential of the power supply, a gate terminal coupled to a first gate signal, and a source terminal and a first PFET having a gate terminal coupled to a second gate signal, a source terminal coupled to the first voltage potential, and a drain terminal coupled to the source terminal of the NFET thereby forming a common node,
wherein a level of a current coupled from the commode node to the dynamic node corresponds to a combination of a source current of the NFET and a drain current of the first PFET and is determined in response to a level of the first gate signal, a level of the second gate signal, and a voltage level of the common node.

12. The processor of claim 11, wherein the gate terminal of the first PFET is coupled to a second voltage potential of the power supply as the first gate signal.

13. The processor of claim 12, wherein the gate terminal of the NFET is coupled to the first voltage potential as the second gate signal.

14. The processor of claim 13, wherein the current from the common node is coupled to the dynamic node by a second PFET having a source terminal coupled to the common node, a drain terminal coupled to the dynamic node and a gate terminal coupled to the output of the first inverting logic gate.

15. The processor of claim 14, wherein the gate-to-source voltage of the NFET and the level of the common node determine the source current of the NFET.

16. The processor of claim 15, wherein the gate-to-source voltage of the first PFET and the level of the common node determine the drain current of the first PFET.

17. The processor of claim 16, wherein the output of the first inverting circuit is latched to an output in response to the clock signal.

18. The processor of claim 11, further comprising a second inverting circuit having an output coupled to the gate of the NFET and an input coupled to the output of the first inverting circuit and the gate-to source voltage of the NFET is the difference between the output level of the second inverting circuit and a voltage level of the dynamic node.

19. The processor of claim 18, wherein the gate of the first PFET is coupled to the output of the first inverting logic circuit and the gate to source voltage of the first PFET is the difference between the first voltage potential and a voltage of the output of the first inverting logic gate.

20. The processor of claim 19, wherein the common node is coupled directly to the dynamic node.
